(19) United States
(12) Patent Application Publication
(10) Pub. No.: US 2026/0107504 A1
(43) Pub. Date: Apr. 16, 2026

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 19/358,622

(22) Filed: Oct. 15, 2025

(30) Foreign Application Priority Data
Oct. 15, 2024 (JP) 2024-179887
Aug. 20, 2025 (JP) 2025-136831

(51) Int. Cl. H10D 30/67; G02F 1/1368; H10D 30/01

(52) U.S. Cl. CPC H10D 30/6704; H10D 30/031; H10D 30/6715; H10D 30/6755; G02F 1/1368

(57) ABSTRACT

A semiconductor device includes a gate electrode on an insulating surface, a gate insulating layer on the gate electrode, an oxide semiconductor layer on the gate insulating layer, a first insulating layer on the oxide semiconductor layer; and a first patterned layer composed of an insulating material on the first insulating layer. The oxide semiconductor layer has a channel portion and a conductive portion, and the first patterned layer overlaps the channel portion in a planar view.

### CROSS REFERENCE TO RELATED APPLICATIONS

This application claims the benefit of priority to Japanese Patent Application No. 2024-179887, filed on Oct. 15, 2024 and Japanese Patent Application No. 2025-136831, filed on Aug. 20, 2025, the entire contents of which are incorporated herein by reference.

### FIELD

One embodiment of the present invention relates to a semiconductor device and a display device.

### BACKGROUND

In recent years, as a material constituting a semiconductor device, an oxide semiconductor has attracted attention instead of amorphous silicon, polysilicon, and single crystal silicon. In particular, as a semiconductor device including an oxide semiconductor, a thin film transistor using an oxide semiconductor as a channel has been developed (for example, see Japanese Laid-Open Patent Publication No. 2021-141338, Japanese Laid-Open Patent Publication No. 2014-099601, Japanese Laid-Open Patent Publication No. 2021-153196, Japanese Laid-Open Patent Publication No. 2018-006730, Japanese Laid-Open Patent Publication No. 2016-184771, and Japanese Laid-Open Patent Publication No. 2021-108405). A thin film transistor using an oxide semiconductor as a channel can be formed by a simple structure and a low-temperature process as in a semiconductor device using amorphous silicon as a channel. It is known that a thin film transistor using an oxide semiconductor as a channel has a higher field-effect mobility than a thin film transistor using amorphous silicon as a channel.

### SUMMARY

A semiconductor device according to an embodiment of the present invention includes a gate electrode on an insulating surface, a gate insulating layer on the gate electrode, an oxide semiconductor layer on the gate insulating layer, a first insulating layer on the oxide semiconductor layer, and a first patterned layer composed of an insulating material on the first insulating layer. The oxide semiconductor layer has a channel portion and a conductive portion, and the first patterned layer overlaps the channel portion in a planar view.

### BRIEF DESCRIPTION OF THE DRAWINGS

FIG. 1 is a schematic cross-sectional view showing a configuration of a semiconductor device according to an embodiment of the present invention.

FIG. 2 is a schematic planer view showing a configuration of a semiconductor device according to an embodiment of the present invention.

FIG. 3 is a sequence diagram showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a schematic cross-sectional view showing a method for manufacturing a semiconductor device according to an embodiment of the present invention.

FIG. 13 is a schematic cross-sectional view showing a configuration of a semiconductor device according to an embodiment of the present invention.

FIG. 14 is a schematic cross-sectional view showing a configuration of a semiconductor device according to an embodiment of the present invention.

FIG. 15 is a schematic cross-sectional view showing a configuration of a semiconductor device according to an embodiment of the present invention.

FIG. 16 is a sequence diagram showing a method for manufacturing a semiconductor device according to an embodiment of the present invention.

FIG. 17 is a schematic cross-sectional view showing a method for manufacturing a semiconductor device according to an embodiment of the present invention.

FIG. 18 is a schematic cross-sectional view showing a method for manufacturing a semiconductor device according to an embodiment of the present invention.

FIG. 19 is a schematic cross-sectional view showing a method for manufacturing a semiconductor device according to an embodiment of the present invention.

FIG. 20 is a schematic cross-sectional view showing a configuration of a semiconductor device according to an embodiment of the present invention.

FIG. 21 is a schematic cross-sectional view showing a configuration of a semiconductor device according to an embodiment of the present invention.

FIG. 22 is a schematic cross-sectional view showing a configuration of a semiconductor device according to an embodiment of the present invention.

FIG. 23 is a sequence diagram showing a method for manufacturing a semiconductor device according to an embodiment of the present invention.

FIG. 24 is a schematic cross-sectional view showing a method for manufacturing a semiconductor device according to an embodiment of the present invention.

FIG. 25 is a schematic cross-sectional view showing a method for manufacturing a semiconductor device according to an embodiment of the present invention.

FIG. 26 is a schematic cross-sectional view showing a configuration of a semiconductor device according to an embodiment of the present invention.

FIG. 27 is a schematic planer view showing an overall configuration of a display device according to an embodiment of the present invention.

FIG. 28 is a block diagram showing a circuit configuration of a display device according to an embodiment of the present invention.

FIG. 29 is a circuit diagram showing a configuration of a pixel circuit of a display device according to an embodiment of the present invention.

FIG. 30 is a cross-sectional view showing a configuration of a pixel of a display device according to an embodiment of the present invention.

### DESCRIPTION OF EMBODIMENTS

Conventionally, although various device structures including a top gate type structure and a bottom gate type structure have been studied for a thin film transistor using an oxide semiconductor, there are several problems in terms of reliability. For example, in the conventional device structure, it is difficult to achieve both securing withstand voltage characteristics of the gate insulating layer (specifically, a withstand voltage applied between a gate and a source or between the gate and a drain) and suppressing damage to the oxide semiconductor layer. Therefore, there is still room for improvement in reliability of a thin film transistor using a conventional oxide semiconductor.

An object of the present invention is to improve the reliability of a semiconductor device including an oxide semiconductor.

Hereinafter, embodiments of the present invention will be described with reference to the drawings. The following disclosure is merely an example. A configuration that can be easily conceived by a person skilled in the art by appropriately changing a configuration of an embodiment while keeping the gist of the invention is naturally included in the scope of the present invention. In order to make the description clearer, the drawings may schematically show the width, thickness, shape, and the like of each part in comparison with an actual embodiment. However, the shown shapes are merely examples, and do not limit the interpretation of the present invention. In the present specification and the drawings, the same reference signs are given to elements similar to those described above with respect to the drawings described above, and detailed description thereof may be omitted as appropriate.

In each embodiment of the present invention, a direction from the substrate toward the oxide semiconductor layer is referred to as “upper” or “upper”. Conversely, a direction from the oxide semiconductor layer toward the substrate is referred to as “under” or “lower”. As described above, for convenience of explanation, although the term “upper” or “lower” will be used for description, for example, upper and lower relationships between the substrate and the oxide semiconductor layer may be arranged so as to be opposite to that shown in the drawings. In the following description, for example, the expression “oxide semiconductor layer on the substrate” merely describes the vertical relationship between the substrate and the oxide semiconductor layer as described above, and other members may be arranged between the substrate and the oxide semiconductor layer.

A “display device” refers to a structure that displays an image using an electro-optical layer. For example, the term display device may refer to a display panel including an electro-optical layer, or may refer to a structure in which another optical member (for example, a polarizing member, a backlight, a touch panel, or the like) is attached to a display cell. The “electro-optical layer” may include a liquid crystal layer, an electroluminescent (EL) layer, an electrochromic (EC) layer, an electrophoretic layer, as long as there is no technical contradiction. Therefore, although an organic EL display device including an organic EL layer is exemplified as a display device in the embodiment described later, the structure in the present embodiment can be applied to a display device including another electro-optical layer described above, such as a liquid crystal display device including a liquid crystal layer.

As used herein, the phrase “α includes A, B, or C,” “α includes any of A, B, or C,” “α includes one selected from the group consisting of A, B, and C,” or the like does not exclude cases where α includes a plurality of combinations of A to C unless otherwise indicated. Furthermore, these expressions do not exclude the case where α includes other elements.

As used herein, “coincide” means both “substantially coincide” as well as “perfectly coincide”. “Substantially coincide” refers to a case that falls within a range of small differences that do not perfectly coincide but can be considered as coincide, for example, within an error of ±5% (preferably ±3%).

### First Embodiment

A semiconductor device according to an embodiment of the present invention will be described by exemplifying a thin film transistor. The semiconductor device of the embodiment described below may be, for example, an integrated circuit (Integrated Circuit: IC) such as a microprocessor (Micro-Processing Unit: MPU) or a thin film transistor used in a memory circuit, in addition to a thin film transistor used in a display device (for example, an organic EL display device or a liquid crystal display device).

### Configuration of Semiconductor Device

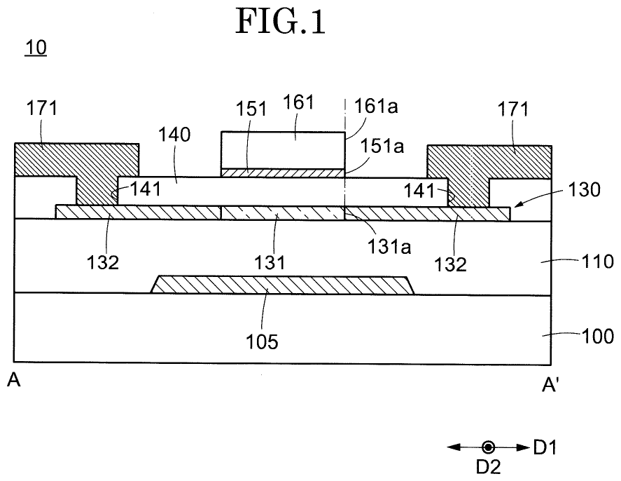

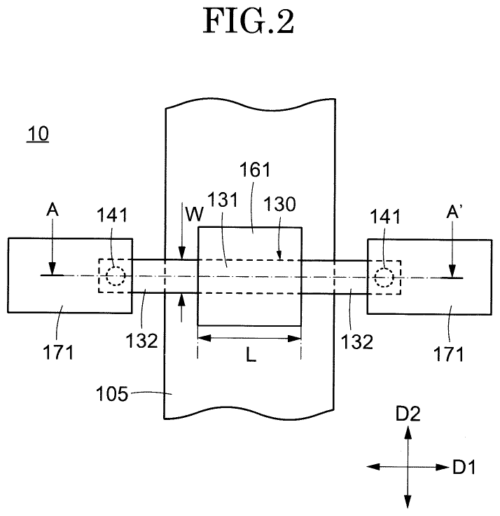

A configuration of the semiconductor device 10 according to an embodiment of the present invention will be described. FIG. 1 is a schematic cross-sectional view showing a configuration of a semiconductor device 10 according to an embodiment of the present invention. FIG. 2 is a schematic planer view showing a configuration of a semiconductor device 10 according to an embodiment of the present invention. Specifically, FIG. 1 corresponds to a cross-sectional view taken along the dash-dot line shown by A-A′ shown in FIG. 2.

First, a cross-sectional structure of the semiconductor device 10 will be described with reference to FIG. 1. As shown in FIG. 1, the semiconductor device 10 is arranged above a substrate 100. The semiconductor device 10 includes a gate electrode 105, a gate insulating layer 110, an oxide semiconductor layer 130, an insulating layer 140, a patterned layer 151 formed of a metal oxide, a patterned layer 161 formed of an insulator, and a terminal electrode 171.

The gate electrode 105 is arranged on the substrate 100. The gate electrode 105 functions as a gate of the semiconductor device 10 (thin film transistor). Specifically, the gate electrode 105 has a function of applying a gate voltage to a channel portion 131 of the oxide semiconductor layer 130, which will be described later. An insulating layer (not shown) may be arranged on the substrate 100. That is, the gate electrode 105 may be arranged directly or indirectly on the substrate 100. In other words, the gate electrode 105 is arranged on the insulating surface.

The gate insulating layer 110 is arranged on the substrate 100 and the gate electrode 105. The gate insulating layer 110 has a function as a barrier film for shielding impurities that diffuse from the substrate 100 toward the oxide semiconductor layer 130, and a function as a base of the oxide semiconductor layer 130 arranged above.

Although not shown, in the present embodiment, the gate insulating layer 110 has a two-layer structure in accordance with the functions described above. Specifically, a silicon nitride layer is used as the insulating layer on a lower layer side (a side closer to the substrate 100), and a silicon oxide layer is used as the insulating layer on an upper layer side (a side closer to the oxide semiconductor layer 130). In the present embodiment, since a thickness of the insulating layer on the lower layer side is 200 nm and a thickness of the insulating layer on the upper layer side is 100 nm, the thickness of the gate insulating layer 110 is 300 nm. That is, in the present embodiment, the thickness of the gate insulating layer 110 may be 200 nm or more (preferably 300 nm or more, more preferably 400 nm or more).

The oxide semiconductor layer 130 is arranged on the gate insulating layer 110. The oxide semiconductor layer 130 includes the channel portion 131 and a conductive portion 132 that are continuous in a first direction. The channel portion 131 functions as a channel region of the semiconductor device 10. The conductive portion 132 functions as a source region or a drain region of the semiconductor device 10. The conductive portion 132 is a region having a lower resistance than the channel portion 131, and has a role of transmitting carriers flowing through the channel portion 131 to the terminal electrode 171.

The insulating layer 140 is arranged on the oxide semiconductor layer 130. In the present embodiment, a silicon oxide layer is used as the insulating layer 140. The insulating layer 140 is a dielectric layer that electrically insulates a layer in which the terminal electrode 171 to be described later is formed and a layer in which an oxide semiconductor layer 130 is formed. A thickness of the insulating layer 140 is 50 nm or more and 200 nm or less (preferably 50 nm or more and 150 nm or less, more preferably 50 nm or more and 100 nm or less). The thickness of the insulating layer 140 is smaller than the thickness of the gate insulating layer 110. Advantages of the thin insulating layer 140 will be described later.

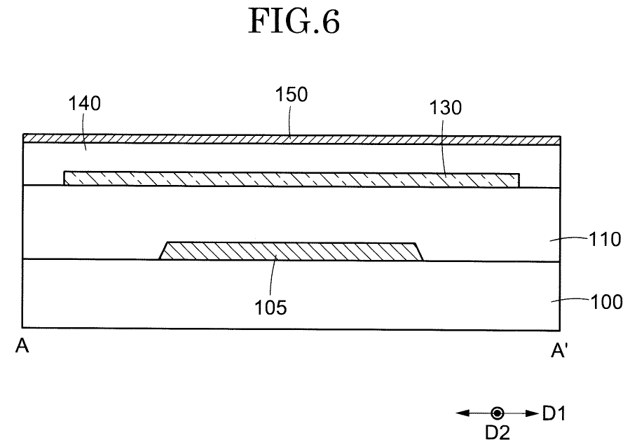

The patterned layer 151 made of a metal oxide is arranged on the insulating layer 140. The patterned layer 151 is obtained by patterning a metal oxide layer into islands. The patterned layer 151 functions as a barrier layer that suppresses hydrogen diffusion from above the channel portion 131 of the oxide semiconductor layer 130. As will be described in detail later, the patterned layer 151 is a layer obtained by patterning the metal oxide layer 150 (see FIG. 6) used for performing a heat treatment for supplying oxygen to the oxide semiconductor layer 130 in the manufacturing process of the semiconductor device 10.

The patterned layer 151 is arranged above the oxide semiconductor layer 130 via the insulating layer 140. That is, the insulating layer 140 is in contact with the oxide semiconductor layer 130 and the patterned layer 151. The patterned layer 151 overlaps the channel portion 131 of the oxide semiconductor layer 130. More specifically, as shown by the dash-dot line in FIG. 1, a position of an edge 151a of the patterned layer 151 and a position of an edge 131a of the channel portion 131 coincide in the vertical direction in the cross-sectional view. In other words, in the cross-sectional view, the position of the edge 151a of the patterned layer 151 and a position of a border between the channel portion 131 and the conductive portion 132 coincide with each other in the vertical direction. The reason why the position of the edge 151a of the patterned layer 151 coincides with the position of the edge 131a of the channel portion 131 will be described later.

The patterned layer 161 made of an insulator is arranged on the patterned layer 151. The patterned layer 161 is obtained by patterning an insulating layer such as silicon oxide into an island shape. The patterned layer 161 functions as a barrier layer that suppresses hydrogen diffusion from above the channel portion 131 of the oxide semiconductor layer 130. For example, in the case where an insulating layer containing a large amount of oxygen or an insulating layer containing a large amount of defects is used as the insulating layer constituting the patterned layer 161, oxygen and defects function as hydrogen traps.

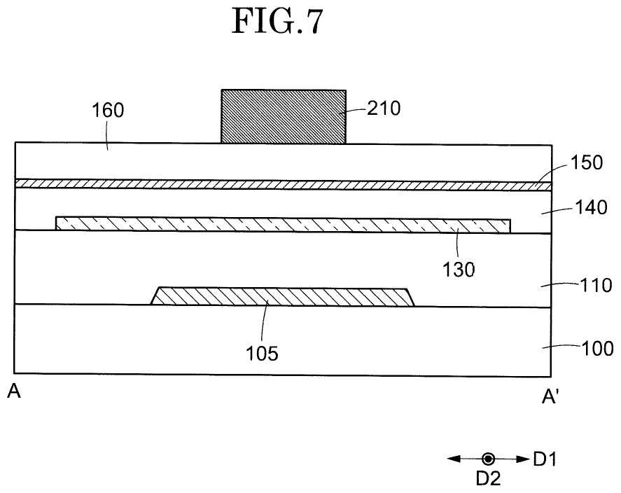

In the present embodiment, since the patterned layer 151 is formed using a resist mask 210 (see FIG. 7) used for patterning the patterned layer 161, the patterned layer 151 and the patterned layer 161 have the same pattern shape. That is, the patterned layer 161 overlaps the channel portion 131 of the oxide semiconductor layer 130 in the same manner as the patterned layer 151. More specifically, as shown by the dash-dot line in FIG. 1, a position of the edge 161a of the patterned layer 161 and the position of the edge 131a of the channel portion 131 coincide in the vertical direction in the cross-sectional view. In other words, in the cross-sectional view, the position of the edge 161a of the patterned layer 161 and the position of the border between the channel portion 131 and the conductive portion 132 coincide with each other in the vertical direction.

The terminal electrode 171 is arranged on the insulating layer 140 and is electrically connected to the conductive portion 132 via a contact hole 141 arranged in the insulating layer 140. The terminal electrode 171 serves to supply a carrier to the conductive portion 132 or to extract a carrier from the conductive portion 132. That is, the terminal electrode 171 functions as a source electrode or a drain electrode of the semiconductor device 10 (thin film transistor) according to the role of the conductive portion 132. Specifically, the terminal electrode 171 functions as a source electrode when the electrically connected conductive portion 132 functions as a source region, and functions as a drain electrode when the electrically connected conductive portion 132 functions as a drain region.

In the present embodiment, although a bottom gate transistor in which the gate electrode 105 is arranged below the oxide semiconductor layer 130 is exemplified as the semiconductor device 10, the present invention is not limited to this configuration. For example, the semiconductor device 10 may be a dual-gate transistor by arranging another gate electrode on the insulating layer 140 (in the example shown in FIG. 1, on the patterned layer 151).

Next, a planar structure of the semiconductor device 10 will be described with reference to FIG. 2. As shown in FIG. 2, the first direction (direction D1) is a direction connecting the two terminal electrodes 171 to each other (a direction in which the channel portion 131 and the conductive portion 132 are continuous), and corresponds to a direction in which the carrier moves. In the oxide semiconductor layer 130, a length in the first direction of the channel portion 131 is a channel length (L), and a length of the channel portion 131 in a second direction (direction D2) is a channel width (W). The second direction is a direction intersecting the first direction. In the present embodiment, although the second direction indicates a direction orthogonal to the first direction, the first direction and the second direction may not be orthogonal to each other depending on the layout of the oxide semiconductor layer 130.

In the present embodiment, in the first direction, a width of the gate electrode 105 is wider than the length (channel length) of the channel portion 131. The reason for such a configuration is to effectively prevent the intrusion of external light into the channel portion 131. However, the present invention is not limited to this example, and the width of the gate electrode 105 may be the same as the length of the channel portion 131.

As shown in FIG. 2, in a planer view, the patterned layer 161 made of an insulator is arranged so as to overlap the oxide semiconductor layer 130. Specifically, in a planer view, the patterned layer 161 is arranged so as to intersect with the channel portion 131 of the oxide semiconductor layer 130. As described above, a width of the patterned layer 161 in the second direction is preferably larger than a width (W) of the oxide semiconductor layer 130 in the second direction. Such a configuration is effective in effectively performing the function described above of the patterned layer 161 (a function of suppressing hydrogen diffusion from above the oxide semiconductor layer 130 to the channel portion 131).

Further, in a planer view, an outer edge of a portion of the patterned layer 161 overlapping the oxide semiconductor layer 130 coincides with an outer edge of the channel portion 131. In other words, the patterned layer 161 intersects the channel portion 131 and does not overlap the conductive portion 132. However, the expression “the patterned layer 161 intersects the channel portion 131 and does not overlap the conductive portion 132” includes a case where the patterned layer 161 overlaps a portion of the conductive portion 132 within an error range. As will be described later, the conductive portion 132 is formed by adding impurities to the oxide semiconductor layer 130 by a method such as ion implantation. Therefore, a case may occur in which a portion of the conductive portion 132 slightly overlaps the patterned layer 161 due to the downward wrapping of impurities in the patterned layer 161. In addition, the positional relationship between the patterned layer 161 and the oxide semiconductor layer 130 has been described here. However, as described above, since the patterned layer 151 and the patterned layer 161 have the same pattern shape, a positional relationship between the patterned layer 151 and the oxide semiconductor layer 130 is also the same.

In FIG. 2, although a configuration in which the terminal electrode 171 does not overlap the gate electrode 105 in a planer view is shown, the configuration is not limited to this configuration. For example, in a planer view, either or both of the two terminal electrodes 171 may overlap the gate electrode 105.

### Material of Each Layer of Semiconductor Device

The substrate 100 can support each layer constituting the semiconductor device 10. As the substrate 100, for example, a light-transmitting rigid substrate such as a glass substrate, a quartz substrate, or a sapphire substrate can be used. As the substrate, a rigid substrate having no light-transmitting property, such as a silicon substrate, can also be used. Further, as the substrate, a light-transmitting flexible substrate such as a polyimide resin substrate, an acrylic resin substrate, a siloxane resin substrate, or a fluorine resin substrate can be used. In order to improve the heat resistance of the substrate 100, impurities may be introduced into the resin substrate. In addition, a substrate on which a silicon oxide film or a silicon nitride film is formed on the rigid substrate or the flexible substrate described above can also be used as the substrate 100.

As described above, since the gate electrode 105 has a larger area than the channel portion 131 of the oxide semiconductor layer 130, it is preferable to use a material capable of blocking external light incident on the channel portion 131. As the gate electrode 105, for example, aluminum (Al), copper (Cu), titanium (Ti), molybdenum (Mo), or tungsten (W), or an alloy or a compound thereof can be used. The gate electrode 105 may have a single-layer structure or a stacked-layer structure.

As the gate insulating layer 110, for example, silicon oxide (SiOx), silicon oxynitride (SiOxNy), silicon nitride (SiNx), silicon nitride oxide (SiNxOy), aluminum oxide (AlOx), aluminum oxynitride (AlOxNy), aluminum nitride oxide (AlNxOy), aluminum nitride (AlNx), or the like can be used. Here, silicon oxynitride (SiOxNy) and aluminum oxynitride (AlOxNy) are silicon compounds and aluminum compounds that respectively contain nitrogen (N) with a smaller ratio (x>y) than oxygen (O). Also, silicon nitride oxide (SiNxOy) and aluminum nitride oxide (AlNxOy) are silicon compounds and aluminum compounds that contain a smaller ratio of oxygen (x>y) than nitrogen. In the present embodiment, the gate insulating layer 110 has a two-layer structure, a silicon nitride layer is used as the lower insulating layer, and a silicon oxide layer is used as the upper insulating layer.

The oxide semiconductor layer 130 may have an amorphous structure or a polycrystalline structure.

The insulating layer 140 includes an insulating oxide. Specifically, as the insulating layer 140, silicon oxide (SiOx), silicon oxynitride (SiOxNy), aluminum oxide (AlOx), aluminum oxynitride (AlOxNy), or the like can be used. In the present embodiment, a silicon oxide layer having a thickness of 50 nm or more and 200 nm or less (preferably, 50 nm or more and 150 nm or less, more preferably, 50 nm or more and 100 nm or less) is used as the insulating layer 140.

The patterned layer 151 is made of a metal oxide. In the present embodiment, an oxide containing aluminum as a main component (for example, aluminum oxide) is used as the metal oxide constituting the patterned layer 151. Since aluminum oxide has a high barrier property against gas, the patterned layer 151 has a function of relaxing hydrogen diffusion into the channel portion 131 of the oxide semiconductor layer 130. A thickness of the patterned layer 151 may be, for example, 5 nm or more and 100 nm or less, 5 nm or more and 50 nm or less, 5 nm or more and 30 nm or less, or 7 nm or more and 15 nm or less.

The patterned layer 161 is made of an insulator. In the present embodiment, as the insulator constituting the patterned layer 161, for example, an insulator containing silicon as a main component such as silicon oxide (SiOx), silicon oxynitride (SiOxNy), silicon nitride (SiNx), or silicon nitride oxide (SiNxOy) can be used. As described above, by using an insulator containing a large amount of oxygen or an insulator containing a large amount of defects as an insulator, the patterned layer 161 can be provided with a function of relaxing hydrogen diffusion into the channel portion 131 of the oxide semiconductor layer 130. A thickness of the patterned layer 161 may be, for example, 100 nm or more and 300 nm or less, 150 nm or more and 250 nm or less, or 175 nm or more and 200 nm or less.

The terminal electrode 171 has conductivity. As the terminal electrode 171, for example, copper (Cu), silver (Ag), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or a compound thereof can be used. The terminal electrode 171 may have a single-layer structure or a stacked-layer structure.

### Method for Manufacturing Semiconductor Device

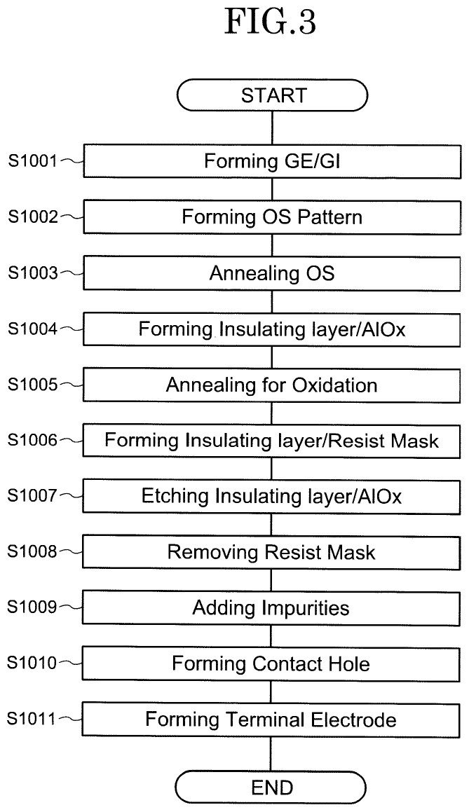

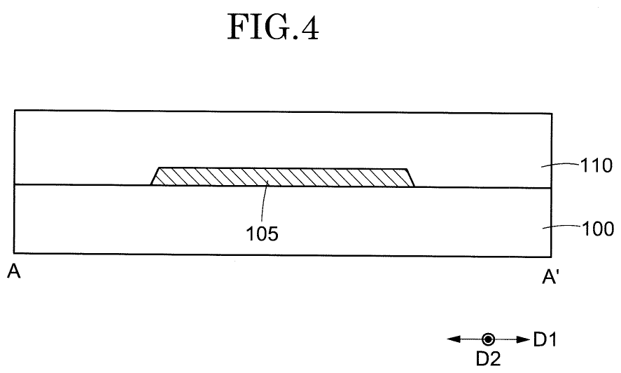

Next, a method for manufacturing the semiconductor device 10 according to an embodiment of the present invention will be described. FIG. 3 is a sequence diagram showing a method for manufacturing the semiconductor device 10 according to an embodiment of the present invention. FIG. 4 to FIG. 12 are schematic cross-sectional views showing a method for manufacturing the semiconductor device 10 according to an embodiment of the present invention.

As shown in FIG. 3 and FIG. 4, the gate electrode 105 is formed on the substrate 100, and the gate insulating layer 110 is formed on the gate electrode 105 (step S1001 in FIG. 4). As the gate insulating layer 110, for example, a stacked structure of a silicon nitride layer and a silicon oxide layer is formed. The gate insulating layer 110 is formed by a CVD (Chemical Vapor Deposition) method. In the present specification, a method for forming a film on a substrate by a sputtering method, the CVD method, or the like is sometimes referred to as “forming a thin film”, and is used in the same sense as “forming a thin film”.

In the case where a silicon nitride layer is arranged as a part of the gate insulating layer 110 on the side close to the substrate 100, impurities that diffuse from the substrate 100 side toward the oxide semiconductor layer 130 can be blocked. In the case where a silicon oxide layer is arranged as a part of the gate insulating layer 110 on a side in contact with the oxide semiconductor layer 130 to be formed later, characteristics of an interface between the gate insulating layer 110 and the oxide semiconductor layer 130 are improved.

In the silicon oxide layer, the oxygen content can be increased by setting the film formation temperature to be relatively low. As will be described later, by increasing the amount of oxygen contained in the gate insulating layer 110, the amount of hydrogen diffused into the oxide semiconductor layer 130 can be reduced. In addition, the film formation temperature of the gate insulating layer 110 may be set to 250° C. or higher and 500° C. or lower (preferably 300° C. or higher and 450° C. or lower, and more preferably 325° C. or higher and 400° C. or lower).

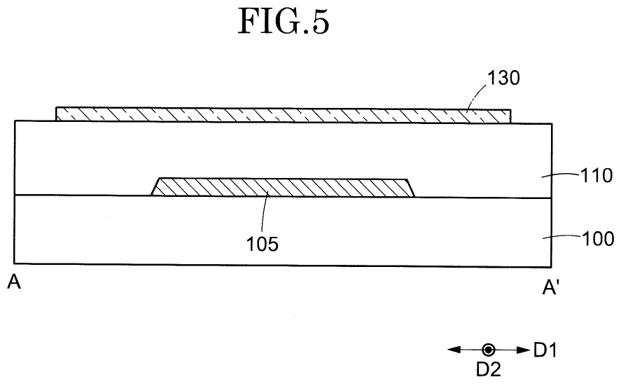

Next, as shown in FIG. 3 and FIG. 5, a patterned oxide-semiconductor layer 130 is formed on the gate insulating layer 110 (step S1002 in FIG. 3). In the present embodiment, the process of forming the oxide semiconductor layer 130 is referred to as “OS patterning”. That is, the oxide semiconductor layer 130 is formed by patterning the oxide semiconductor layer formed on the gate insulating layer 110. In the description of the present embodiment, in the case where the term “oxide semiconductor layer” is used without reference to the drawings, the term “oxide semiconductor layer” refers to an oxide semiconductor layer in a deposited state (that is, a non-processed state).

Etching of the oxide semiconductor layer may be performed by wet etching or dry etching. In the wet etching, for example, an acidic etchant (oxalic acid or hydrofluoric acid) can be used.

In this embodiment, the oxide semiconductor layer is formed by a sputtering method. A thickness of the oxide semiconductor layer to be formed is, for example, 10 nm or more and 100 nm or less, 15 nm or more and 70 nm or less, 15 nm or more and 40 nm or less.

When thin film formation is performed on the substrate by the sputtering method, ions generated in the plasma and atoms recoiled by the sputtering target collide with an object to be formed (specifically, a structure formed on the substrate 100), so that the temperature of the substrate increases in the thin film formation process.

In order to control the temperature (that is, the film formation temperature) of the substrate at the time of forming the oxide semiconductor layer, for example, thin film formation may be performed while cooling the substrate. For example, as the film formation temperature becomes 100° C. or less, 70° C. or less, 50° C. or less, or 30° C. or less, the substrate can be cooled from the opposite side surface of the surface to be formed. In particular, the film formation temperature of the oxide semiconductor layer of the present embodiment is preferably 50° C. or lower. In the present embodiment, the oxide semiconductor layer is formed at a film forming temperature of 50° C. or lower, and OS annealing, which will be described later, is performed at a heated temperature of 400° C. or higher. As described above, in the present embodiment, a difference between the temperature at which the oxide semiconductor layer is formed and the temperature at which OS annealing is performed on the oxide semiconductor layer 130 is preferably 350° C. or higher.

Next, after the oxide semiconductor layer 130 is formed by patterning, a heat treatment (OS annealing) is performed on the oxide semiconductor layer 130 (step S1003 in FIG. 3). In OS annealing, the oxide semiconductor layer 130 is subjected to a heat treatment in an atmosphere at a temperature of 250° C. or higher and 500° C. or lower (preferably 300° C. or higher and 500° C. or lower, and more preferably 350° C. or higher and 450° C. or lower). The heating atmosphere is not limited to an atmospheric atmosphere, but is preferably an oxidizing atmosphere (an atmosphere containing oxygen). Further, the treatment time of the heat treatment is 15 minutes or more and 120 minutes or less, or 30 minutes or more and 60 minutes or less after the predetermined temperature is reached.

In the present embodiment, the substrate on which the oxide semiconductor layer 130 is formed is put into a heating furnace having a heating medium (for example, a support plate) that is maintained at a preset temperature (250° C. or higher and 500° C. or lower). The support plate as the heating medium has a role of supporting the substrate and a role of heating the substrate and a coating film (including the oxide semiconductor layer 130) formed on the substrate. When the substrate on which the oxide semiconductor layer 130 is formed is placed on the support plate, the oxide semiconductor layer 130 is rapidly heated. In the case where the substrate is placed in the heating furnace, it is desirable to keep the temperature drop of the support plate within 15%, 10%, or 5% of the set temperature. That is, the temperature of the support plate is preferably controlled so that the oxide semiconductor layer 130 reaches the set temperature in as short a time as possible.

Next, as shown in FIG. 3 and FIG. 6, the insulating layer 140 and the metallic oxide layer 150 are formed (step S1004 in FIG. 3). For example, a silicon oxide layer is formed as the insulating layer 140. The insulating layer 140 is formed by the CVD method. In the present embodiment, the film formation temperature of the insulating layer 140 is 350° C. A thickness of the insulating layer 140 is, for example, 50 nm or more and 200 nm or less, 50 nm or more and 150 nm or less, or 50 nm or more and 100 nm or less. In the present embodiment, the thickness of the insulating layer 140 is defined as 100 nm.

The metal oxide layer 150 is formed by the sputtering method. By using the sputtering method for forming the metal oxide layer 150, oxygen is implanted into the insulating layer 140 when the metal oxide layer 150 is formed. Therefore, a large amount of oxygen is contained in the insulating layer 140 after the metal oxide layer 150 is formed. A thickness of the metal oxide layer 150 is, for example, 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 150. As described above, since aluminum oxide has a high barrier property against gas, it is possible to prevent the oxygen implanted in the insulating layer 140 from diffusing upward during the heat treatment described later.

In the case where the metal oxide layer 150 is formed by the sputtering method, a process gas used in sputtering remains in a film of the metal oxide layer 150. For example, in the case where Ar is used as the process gas for sputtering, Ar may remain in the film of the metal oxide layer 150. The remaining Ar can be detected by SIMS (Secondary Ion Mass Spectrometry) spectrometry or the like with respect to the metal oxide layer 150. That is, in the case where Ar is used as the sputtering process gas, Ar is detected by SIMS spectrometry or the like on the patterned layer 151 obtained by patterning the metal oxide layer 150.

Next, while the metal oxide layer 150 is formed on the insulating layer 140, a heat treatment (oxidation annealing) for supplying oxygen to the oxide semiconductor layer 130 is performed (step S1005 in FIG. 3). In a process between the formation of the oxide semiconductor layer 130 and the formation of the insulating layer 140 on the oxide semiconductor layer 130, oxygen vacancies may occur on an upper surface and a side surface of the oxide semiconductor layer 130. Oxygen released from the gate insulating layer 110 and the insulating layer 140 is supplied to the oxide semiconductor layer 130 by the oxidation annealing, and the oxygen vacancy is repaired. The oxidation annealing may be performed at a temperature of 250° C. or higher and 500° C. or lower (preferably 300° C. or higher and 500° C. or lower, and more preferably 350° C. or higher and 450° C. or lower).

Oxygen released from the gate insulating layer 110 and the insulating layer 140 is supplied to the oxide semiconductor layer 130 by oxidation annealing. In the case where a silicon nitride layer is used as a part of the gate insulating layer 110, although hydrogen may be released from the gate insulating layer 110 by the oxidation annealing described above, most of the released hydrogen is captured by oxygen contained in the silicon oxide layer arranged on an upper side before reaching the oxide semiconductor layer 130.

As described above, oxygen can be supplied to the oxide semiconductor layer 130 by the oxidation annealing. During the oxidation annealing, diffusion upwards of the oxygen implanted in the insulating layer 140 is blocked by the metal oxide layer 150, and thus is suppressed from being released into the atmosphere. Therefore, oxygen can be efficiently supplied to the oxide semiconductor layer 130 during the oxidation annealing.

Next, as shown in FIG. 3 and FIG. 7, an insulating layer 160 is formed on the metal oxide layer 150, and the resist mask 210 is further formed on the insulating layer 160 (step S1006 in FIG. 3). As the insulating layer 160 of the present embodiment, a silicon oxynitride (SiOxNy) layer is used. Since the insulating layer 160 is a silicon oxynitride layer, the oxygen content can be increased by setting the film formation temperature to be relatively low. By increasing the amount of oxygen contained in the insulating layer 160, hydrogen diffusion from above the oxide semiconductor layer 130 can be effectively suppressed. In addition, the film formation temperature of the insulating layer 160 may be set to 250° C. or higher and 500° C. or lower (preferably 300° C. or higher and 450° C. or lower, and more preferably 325° C. or higher and 400° C. or lower).

The resist mask 210 is arranged so as to overlap the oxide semiconductor layer 130. As will be described later, a portion of the oxide semiconductor layer 130 that overlaps the resist mask 210 corresponds to a portion where the channel portion 131 is formed. As shown in FIG. 2, the resist mask 210 is arranged so as to intersect the oxide semiconductor layer 130 in the second direction.

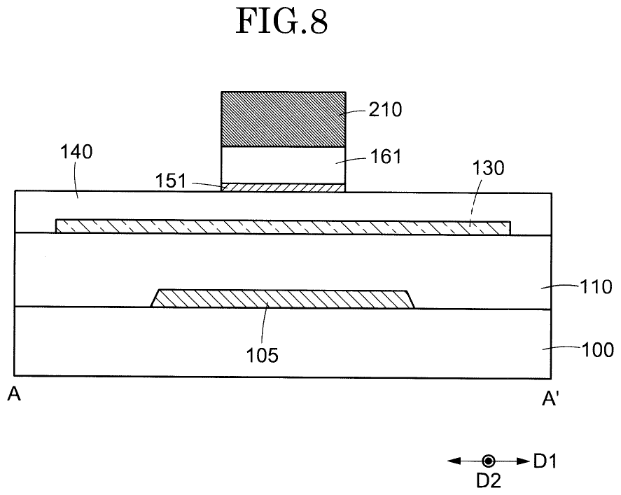

Next, as shown in FIG. 3 and FIG. 8, by using the resist mask 210 as a mask, the metal oxide layer 150 and the insulating layer 160 are etched to form the patterned layer 151 made of a metal oxide and the patterned layer 161 made of an insulator (step S1007 in FIG. 3). The etching of the metal oxide layer 150 and the insulating layer 160 may be wet etching or dry etching. In wet etching, for example, dilute hydrofluoric acid (DHF) is used.

When the insulating layer 160 is etched, selectivity between the metal oxide layer 150 and the insulating layer 160 is preferably large. If the selectivity is large, the metal oxide layer 150 can be used as an etching stopper in etching the insulating layer 160. In this case, after the insulating layer 160 is etched, the metal oxide layer 150 may be etched by changing the etchant or the etching gas. In addition, when the metal oxide layer 150 is etched, selectivity between the insulating layer 140 and the metal oxide layer 150 is preferably large.

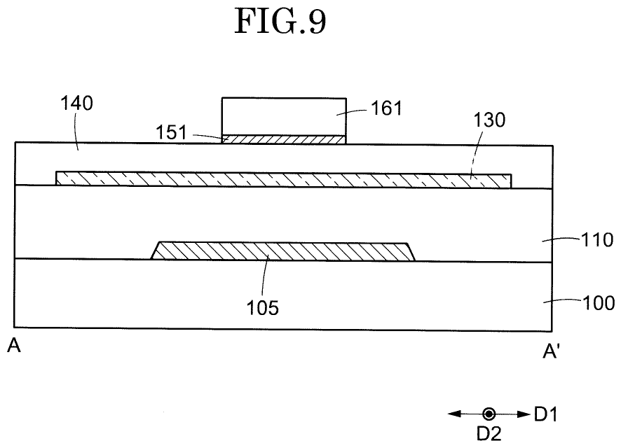

Next, as shown in FIG. 3 and FIG. 9, the resist mask 210 is removed (step S1008 in FIG. 3). By removing the resist mask 210, the patterned layer 151 made of a metal oxide and the patterned layer 161 made of an insulator remain on the insulating layer 140.

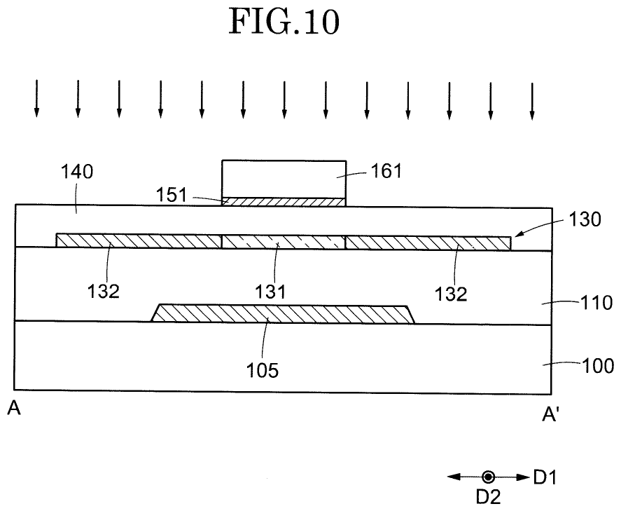

Next, as shown in FIG. 3 and FIG. 10, ions are implanted from above the patterned layer 161 made of an insulator, and impurities are added to the oxide semiconductor layer 130 (step S1009 in FIG. 3). As the impurity, phosphorus, boron, argon, or the like can be used. Since the purpose of adding the impurity is to increase the conductivity by forming an oxygen vacancy with respect to a partial region of the oxide semiconductor layer 130, an element having a large atomic radius is preferably used as the impurity. In the present embodiment, although an example in which an impurity is added by ion implantation is shown, ion doping may be used. In the present embodiment, boron is added using ion implantation. Although conditions of ion implantation of the present embodiment are an acceleration voltage of 30 keV and a dose of 1×10¹⁵/cm², they are not limited to this example.

As shown in FIG. 10, when an impurity is ion-implanted into the oxide semiconductor layer 130, the conductive portion 132 is formed in the oxide semiconductor layer 130. In this case, a region where the impurity is not implanted and an original state is maintained functions as the channel portion 131. That is, in the cross-sectional view, the positions of the edges of the patterned layer 151 and the patterned layer 161 coincide with the positions of the edges of the channel portion 131 in the vertical direction.

Impurities are added to the conductive portion 132 via the insulating layer 140. As described above, the conductive portion 132 functions as a source region or a drain region of the semiconductor device 10.

In the present embodiment, since the insulating layer 140 does not need to be used as the gate insulating layer, a thickness can be set to be 50 nm or more and 200 nm or less (preferably 50 nm or more and 150 nm or less, and more preferably 50 nm or more and 100 nm or less). In addition, since the metal oxide layer 150 is removed in a region other than the region directly under the patterned layer 161, the insulating layer 140 is exposed. That is, impurities can be added to the oxide semiconductor layer 130 without passing through the metal oxide layer having a high barrier property against gas. As described above, in the present embodiment, the thickness of the insulating layer 140 can be reduced, and since it is not necessary to pass through the dense metal oxide layer, the dose of the impurity can be increased even at a relatively low acceleration voltage. That is, since a sufficient amount of impurities can be added to the oxide semiconductor layer 130 without imposing an excessive burden on the manufacturing apparatus used for the impurity addition, a resistance value of the conductive portion 132 can be sufficiently reduced.

Further, in the present embodiment, since the patterned layer 161 can be used as a mask, it is not necessary to add impurities using the resist mask 210 as a mask. When a large amount of impurities is implanted into the resist mask 210, although the resist mask 210 may be difficult to remove, in the present embodiment, such a problem does not occur. However, the present invention is not limited to this example, and the impurity may be added while leaving the resist mask 210 on the patterned layer 161.

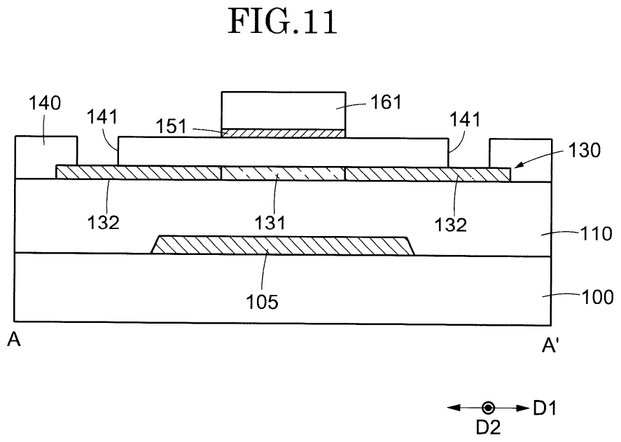

Next, as shown in FIG. 3 and FIG. 11, the contact hole 141 is formed in the insulating layer 140 (step S1010 in FIG. 3). The contact hole 141 exposes a portion of the conductive portion 132. In this case, in the present embodiment, since the metal oxide layer 150 located directly above the conductive portion 132 is removed, there is an advantage that the contact hole 141 is easily formed.

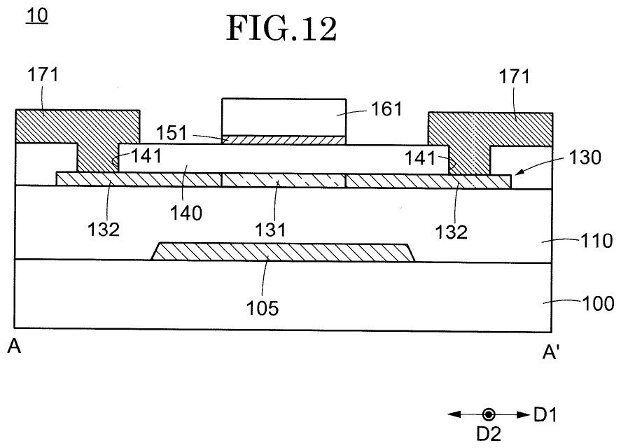

Finally, as shown in FIG. 3 and FIG. 12, the terminal 171 is formed on the conductive portion 132 exposed by the contact hole 141 (step S1011 in FIG. 3). The process described above completes the semiconductor device 10 shown in FIG. 1.

In the semiconductor device 10 of the present embodiment, an insulating layer having a thickness of 200 nm or more (preferably 300 nm or more) can be used as the gate insulating layer 110, so that a breakdown voltage of the gate insulating layer can be sufficiently ensured. In addition, when the conductive portion 132 is formed in the oxide semiconductor layer 130, since the resistance is reduced by adding an impurity through the insulating layer 140, damage to the oxide semiconductor layer 130 (in particular, damage to the channel portion 131) can be suppressed. In this case, since the thickness of the insulating layer 140 is 200 nm or less (preferably 150 nm or less), the resistivity of the conductive portion 132 can be sufficiently reduced by adding a sufficient amount of impurities while suppressing the load on the device used for the impurity addition. As described above, according to the present embodiment, reliability of the semiconductor device 10 including the oxide semiconductor can be improved.

“Field-effect mobility” in the present specification means a maximum value of the field-effect mobility in a region in which a potential difference (Vd) between the source and the drain in the saturated region of the semiconductor device 10 is larger than a value (Vg−Vth) obtained by subtracting the threshold voltage (Vth) of the semiconductor device 10 from the voltage (Vg) supplied to the gate.

### Modification 1 of First Embodiment

In the semiconductor device 10 described above, although an example has been described in which the metal oxide layer 150 is etched to form the patterned layer 151 made of a metal oxide, it is also possible to leave the metal oxide layer 150 without etching.

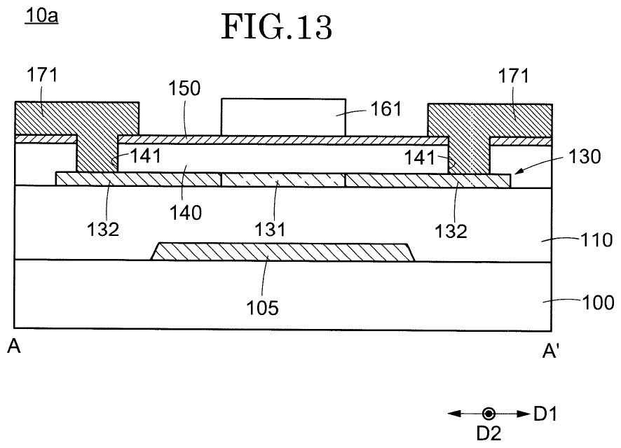

FIG. 13 is a schematic cross-sectional view showing a configuration of a semiconductor device 10a according to a modification of the embodiment. In the semiconductor device 10a of the present modification, the metal oxide layer 150 remains on the insulating layer 140 without being patterned. That is, the metal oxide layer 150 overlaps the conductive portion 132 in addition to the channel portion 131 of the oxide semiconductor layer 130.

In the semiconductor device 10a of the present modification, the metal oxide layer 150 functions as a barrier layer that suppresses hydrogen diffusion from above to the oxide semiconductor layer 130, similar to the patterned layer 151 shown in FIG. 1.

### Modification 2 of First Embodiment

In the semiconductor device 10 described above, although an example has been described in which the metal oxide layer 150 is etched to form the patterned layer 151 made of a metal oxide, the metal oxide layer 150 can be etched and removed without being patterned.

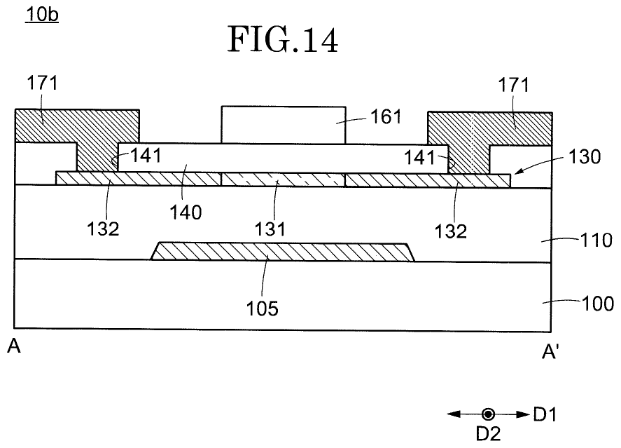

FIG. 14 is a schematic cross-sectional view showing a configuration of a semiconductor device 10b according to a modification of an embodiment. In the semiconductor device 10b of the present modification, after the oxidation annealing shown in step S1005 of FIG. 3, the metal oxide layer 150 formed on the insulating layer 140 is completely removed by etching. That is, in the present modification, the metal oxide layer 150 or the patterned layer 151 made of a metal oxide is not present on the insulating layer 140.

According to this modification, in the process of adding an impurity to the oxide semiconductor layer 130 shown in S1008 of FIG. 3, the dose of the impurity to be added can be sufficiently increased even if the acceleration voltage is set low. Further, according to this modification, the contact hole 141 can be easily formed in the insulating layer 140 shown in S1010 of FIG. 3.

In addition, in this modification, dry etching is preferably used when the insulating layer 160 is etched to form the patterned layer 161 made of an insulator. In the present embodiment, the insulating layer 140 serving as the base is a silicon oxide layer, and the insulating layer 160 is a nitrogen oxide silicon layer in which nitrogen is contained in the silicon oxide layer. Therefore, an endpoint of the etching of the insulating layer 160 can be confirmed by monitoring the amount of nitrogen in the reaction gas. By using this technique, after the patterned layer 161 made of an insulator is formed, over-etching of the insulating layer 140 serving as a base can be prevented.

### Second Embodiment

In the present embodiment, a semiconductor device 20 having a layer structure different from that of the semiconductor device 10 of the first embodiment will be described. In the description of the present embodiment, the same reference signs are used to denote the same elements as those of the first embodiment, and the description thereof may be omitted.

### Configuration of Semiconductor Device

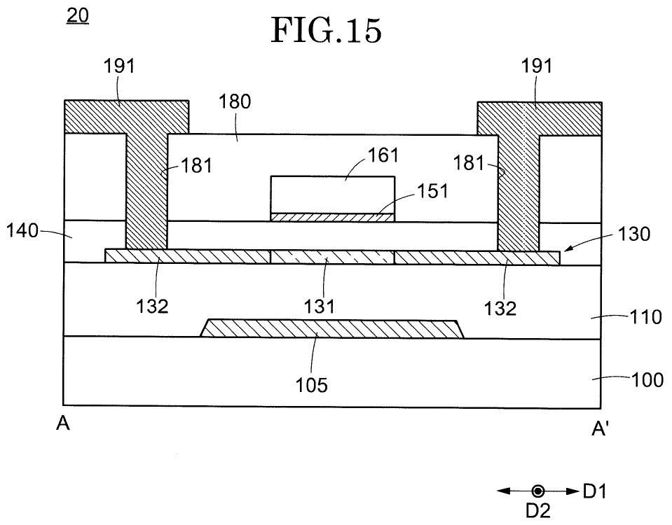

FIG. 15 is a schematic cross-sectional view showing a configuration of the semiconductor device 20 according to an embodiment of the present invention. The difference from the semiconductor device 10 shown in FIG. 1 is that an insulating layer 180 is arranged on the insulating layer 140 and the patterned layer 161 made of an insulator, and that a terminal electrode 191 is arranged on the insulating layer 180.

In the present embodiment, the insulating layer 140 and the insulating layer 180 are used to insulate the oxide semiconductor layer 130 from the terminal electrode 191. The insulating layer 180 may be any insulating layer selected from, for example, silicon oxide (SiOx), silicon nitride (SiNx), silicon oxynitride (SiOxNy), or silicon nitride oxide (SiOxNy). The insulating layer 180 may be made of a resin material such as acrylic or polyimide. Furthermore, the insulating layer 180 may have a single-layer structure including a layer made of the material described above, or may have a stacked-layer structure.

The terminal electrode 191 is electrically connected to the conductive portion 132 of the oxide semiconductor layer 130 through a contact hole 181 formed in a stacked structure including the insulating layer 140 and the insulating layer 180. In the present embodiment, a layer in which the terminal electrode 191 is formed and the layer in which the oxide semiconductor layer 130 is formed are separated by a distance corresponding to a total thickness of the insulating layers 140 and 180. Therefore, there is an advantage that the insulating property between the layer in which the terminal electrode 191 is formed and the layer in which the oxide semiconductor layer 130 is formed is high.

Other effects produced by the semiconductor device 20 of the present embodiment are the same as those of the semiconductor device 10 of the first embodiment.

### Method for Manufacturing Semiconductor Device

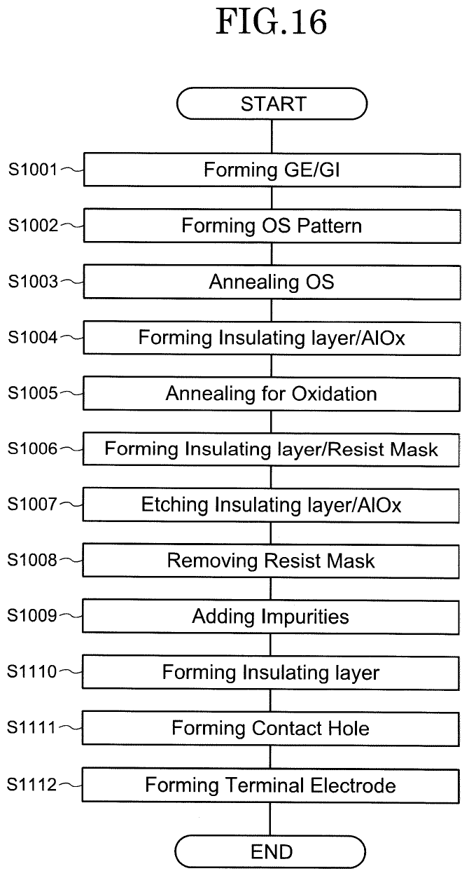

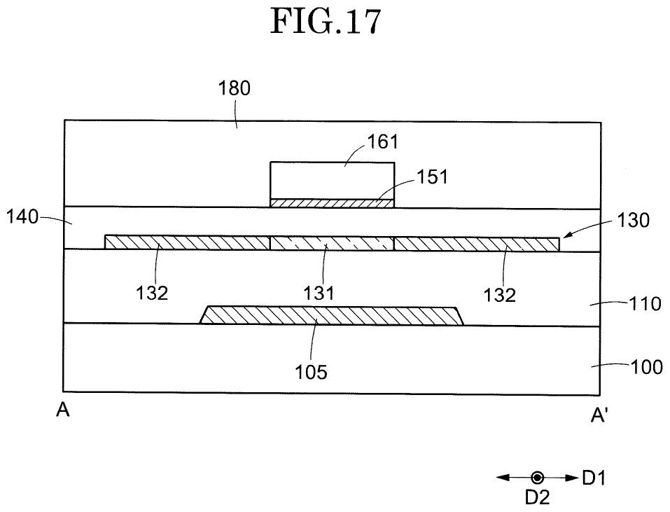

Next, a method for manufacturing the semiconductor device 20 according to an embodiment of the present invention will be described. FIG. 16 is a sequence diagram showing a method for manufacturing the semiconductor device 20 according to the embodiment of the present invention. FIG. 17 to FIG. 19 are schematic cross-sectional views showing a method for manufacturing the semiconductor device 20 according to an embodiment of the present invention.

The manufacturing method for the semiconductor device 20 of the present embodiment is the same as the manufacturing method described in the first embodiment from the processes of step S1001 to step S1009 shown in FIG. 3 of the first embodiment. The manufacturing method for the present embodiment differs from the manufacturing method of the first embodiment in that step S1110 to step S1112 shown in FIG. 16 are included in place of step S1010 and step S1011 shown in FIG. 3.

As in the first embodiment, after the impurities are added to the oxide semiconductor layer 130 in step S1001 to step S1009 of FIG. 3, the insulating layer 180 is formed on the patterned layer 161 formed of the insulating layer 140 and the insulating material as shown in FIG. 16 and FIG. 17 (step S1110 in FIG. 16). As described above, the material of the insulating layer 180 may be any material selected from silicon oxide (SiOx), silicon nitride (SiNx), silicon oxynitride (SiOxNy), silicon nitride oxide (SiOxNy), or resin.

In the present embodiment, as the insulating layer 180, a stacked-layer structure including a silicon oxide layer and a silicon nitride layer is formed using the CVD method. A thickness of the insulating layer 180 may be, for example, 30 nm or more and 500 nm or less. In the present embodiment, a thickness of the silicon oxide layer on a lower side is 100 nm, and a thickness of the silicon nitride layer on an upper side is 300 nm. That is, the thickness of the insulating layer 180 of the present embodiment is 400 nm. However, the thickness of the insulating layer 180 is not limited to this example, and may be thicker or thinner.

Film formation temperature of the insulating layer 180 is preferably set to 250° C. or higher and 500° C. or lower (preferably 300° C. or higher and 450° C. or lower, and more preferably 325° C. or higher and 400° C. or lower).

The insulating layer 180 functions as a passivation layer (protective layer) for preventing gas and moisture from entering from the outside. In addition, as described above, the terminal electrode 191 and the conductive portion 132 of the oxide semiconductor layer 130 are isolated from each other. Further, in the present embodiment, since a silicon nitride layer is used as a part of the insulating layer 180, it is possible to promote the reduction of the resistance of the conductive portion 132.

In forming the silicon nitride layer by the CVD method, since ammonia is used as the source gas, the silicon nitride layer contains a large amount of hydrogen. Therefore, since the insulating layer 180 is heated when the insulating layer 180 is formed and after the insulating layer 180 is formed, hydrogen diffuses from the silicon nitride layer. The diffused hydrogen reaches the conductive portion 132 via the silicon oxide layer and the insulating layer 140 on the lower side of the insulating layer 180. In this case, hydrogen is trapped in the oxygen vacancy inside the conductive portion 132 formed by the ion implantation described above, and a donor level is formed. As a result, the resistance of the conductive portion 132 is reduced. In this case, the patterned layer 151 formed of a metal oxide (aluminum oxide) or the patterned layer 161 formed of an insulator (silicon oxynitride) functions as a barrier layer that suppresses the movement of hydrogen that diffuses from the insulating layer 170 toward the channel portion 131 of the oxide semiconductor layer 130.

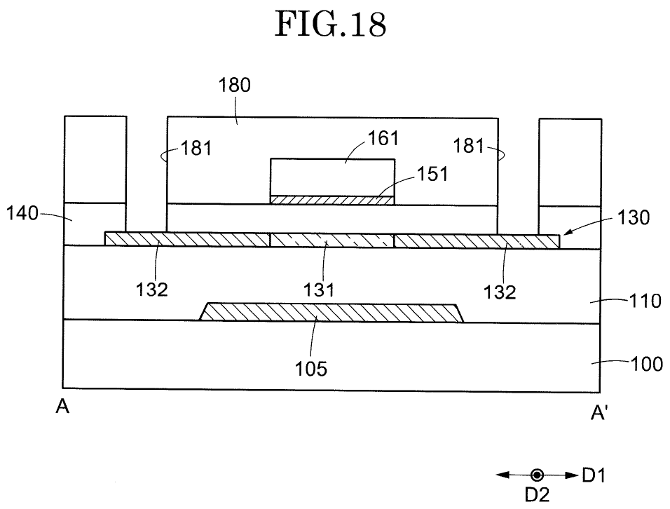

Next, as shown in FIG. 16 and FIG. 18, the contact hole 181 is formed in the stacked structure including the insulating layer 140 and the insulating layer 180 (step S1111 in FIG. 16). The contact hole 181 exposes a portion of the conductive portion 132. In the present embodiment, as in the first embodiment, since the metal oxide layer 150 located directly above the conductive portion 132 is removed, there is an advantage that the contact hole 181 is easily formed.

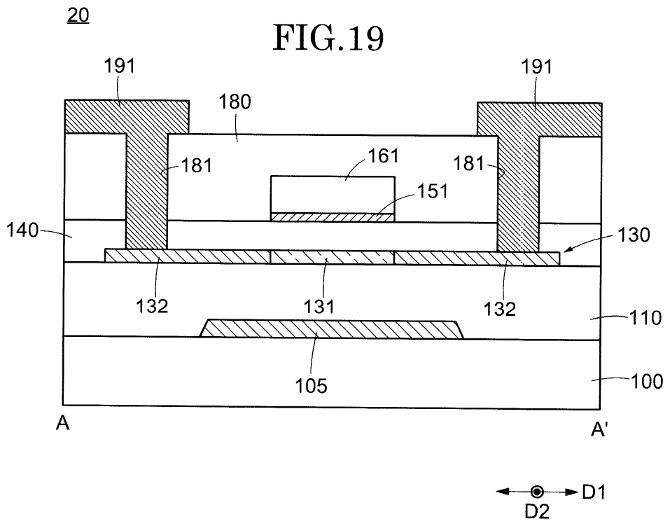

Finally, as shown in FIG. 16 and FIG. 19, the terminal 191 is formed on the conductive portion 132 exposed by the contact hole 181 (step S1112 in FIG. 16). Through the process described above, the semiconductor device 20 shown in FIG. 15 is completed.

### Modification 1 of Second Embodiment

In the semiconductor device 20 described above, although an example has been described in which the metal oxide layer 150 is etched to form the patterned layer 151 made of a metal oxide, it is also possible to leave the metal oxide layer 150 without etching.

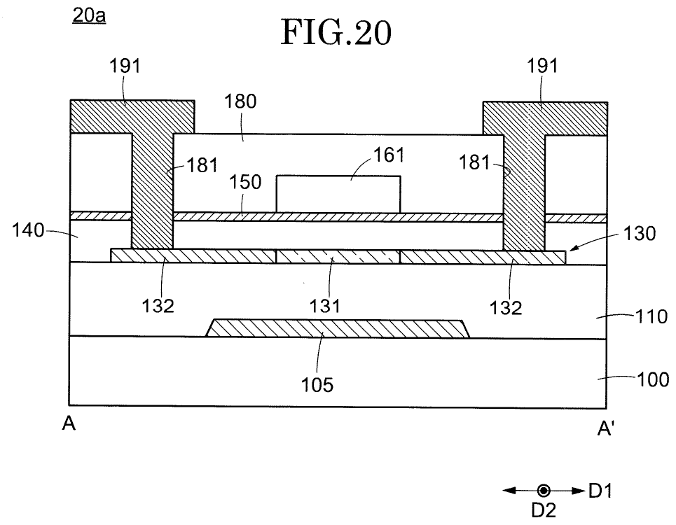

FIG. 20 is a schematic cross-sectional view showing a configuration of a semiconductor device 20a according to a modification of the embodiment. In the semiconductor device 20a of the present modification, the metal oxide layer 150 remains on the insulating layer 140 without being patterned. That is, the metal oxide layer 150 overlaps the conductive portion 132 in addition to the channel portion 131 of the oxide semiconductor layer 130.

In the semiconductor device 20a of the present modification, the metal oxide layer 150 functions as a barrier layer that suppresses hydrogen diffusion from above to the oxide semiconductor layer 130, similar to the patterned layer 151 shown in FIG. 15.

### Modification 2 of Second Embodiment

In the semiconductor device 20 described above, although an example has been described in which the metal oxide layer 150 is etched to form the patterned layer 151 made of a metal oxide, the metal oxide layer 150 can be etched and removed without being patterned.

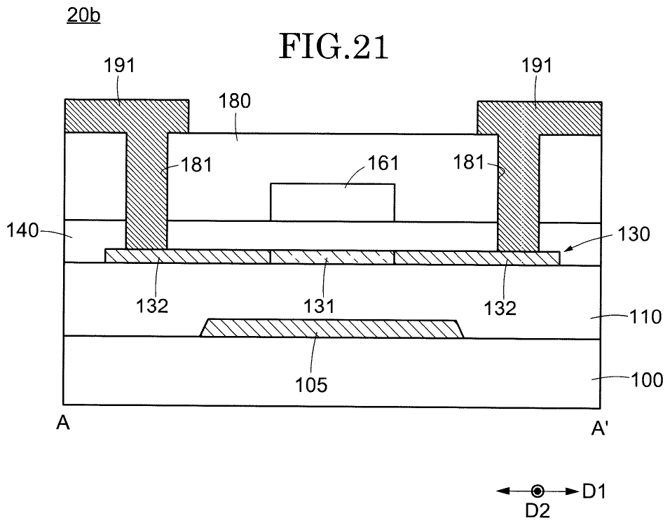

FIG. 21 is a schematic cross-sectional view showing a configuration of a semiconductor device 20b according to a modification of an embodiment of the prevent invention. In the semiconductor device 20b of the present modification, after the oxidation annealing shown in step S1005 of FIG. 16, the metal oxide layer 150 formed on the insulating layer 140 is completely removed by etching. That is, in the present modification, the metal oxide layer 150 or the patterned layer 151 made of a metal oxide is not present on the insulating layer 140.

According to this modification, in the process of adding an impurity to the oxide semiconductor layer 130 shown in S1008 of FIG. 16, the dose of the impurity to be added can be sufficiently increased even if the acceleration voltage is set low. In addition, according to this modification, the contact hole 181 can be easily formed in the stacked structure including the insulating layer 140 and the insulating layer 180 shown in S1111 of FIG. 16.

### Third Embodiment

In the present embodiment, a semiconductor device 30 in which the structure of the oxide semiconductor layer 130 is different from that of the semiconductor device 20 of the second embodiment will be described. In the description of the present embodiment, the same reference signs are used to denote the same elements as those of the second embodiment, and the description thereof may be omitted.

### Configuration of Semiconductor Device

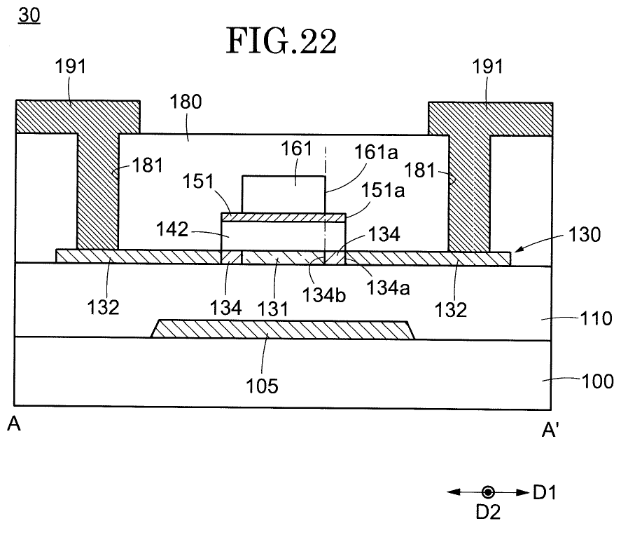

FIG. 22 is a schematic cross-sectional view showing a configuration of the semiconductor device 30 according to an embodiment of the present invention. A difference from the semiconductor device 20 shown in FIG. 15 is that a LDD portion 134 is provided in the oxide semiconductor layer 130. “LDD” is an abbreviation for “Light Doped Drain”. That is, LDD portion 134 indicates a portion having a resistance value lower than that of the channel portion 131 and a resistance value higher than that of the conductive portion 132. As shown in FIG. 22, the LDD portion 134 is arranged between the channel portion 131 and the conductive portion 132. In other words, in the oxide semiconductor layer 130 of the present embodiment, the channel portion 131, the LDD portion 134, and the conductive portion 132 are continuous in the first direction.

The patterned layer 151 made of the metal oxide overlaps the channel portion 131 and the conductive portion 132. In the present embodiment, in a cross-sectional view, the position of the edge 151a of the patterned layer 151 and the position of an edge 134a of the LDD portion 134 on the conductive portion 132 side coincide with each other in the vertical direction. In other words, in the cross-sectional view, the position of the edge 151a of the patterned layer 151 and a position of a border between the LDD portion 134 and the conductive portion 132 coincide with each other in the vertical direction. As described above, in the present embodiment, since a width of the patterned layer 151 is wider than the width of the channel portion 131 in the first direction, the function described above (the function of suppressing the diffusion of hydrogen from above to the channel portion 131 of the oxide semiconductor layer 130) of the patterned layer 151 is effective. However, the configuration is not limited to this configuration, and the patterned layer 151 may not overlap the LDD portion 134.

In addition, the patterned layer 161 made of an insulator overlaps the channel portion 131. In the present embodiment, in the cross-sectional view, the position of the edge 161a of the patterned layer 161 and the position of an edge 134b of the LDD portion 134 on the channel portion 131 side coincide with each other in the vertical direction. In other words, in the cross-sectional view, the position of the edge 161a of the patterned layer 161 and the position of the border between the channel portion 131 and the LDD portion 134 coincide with each other in the vertical direction.

Further, in the example shown in FIG. 22, a portion of the insulating layer 140 overlapping the conductive portion 132 is removed, and a patterned layer 142 made of an insulator is formed. That is, in the semiconductor device 30 of the present embodiment, the insulating layer 180 is in contact with a side surface of the patterned layer 142 and the conductive portion 132.

Other effects produced by the semiconductor device 30 of the present embodiment are the same as those of the semiconductor device 10 of the first embodiment.

### Method for Manufacturing Semiconductor Device

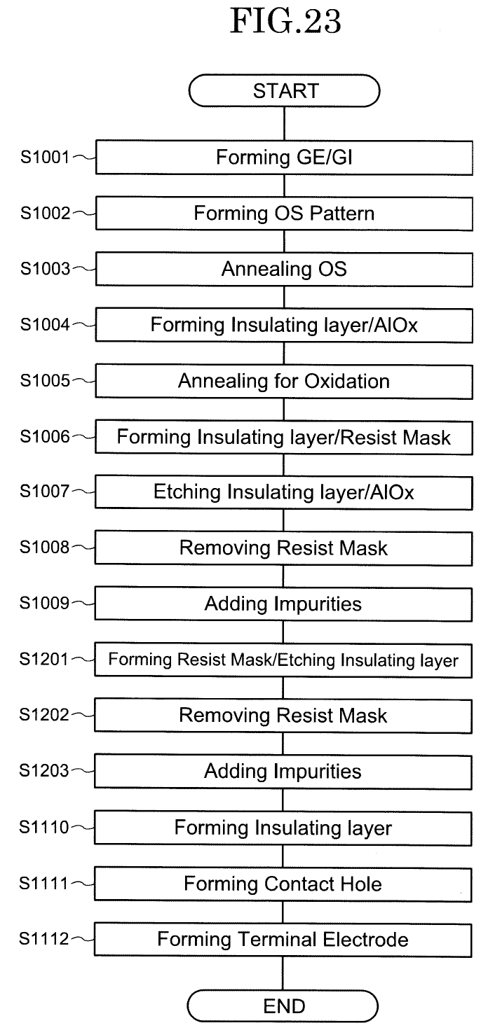

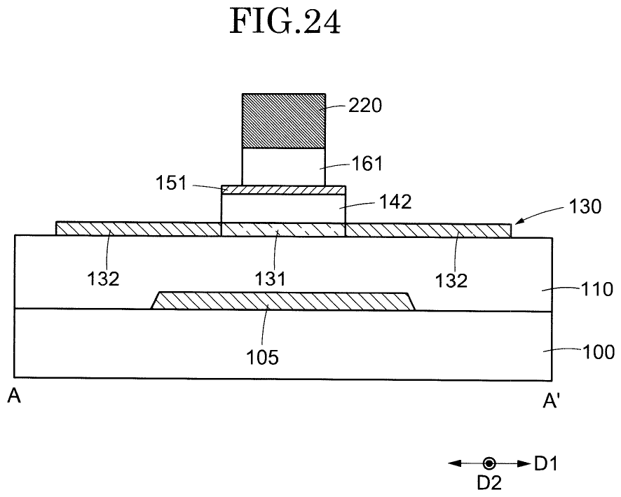

Next, a method for manufacturing the semiconductor device 30 according to an embodiment of the present invention will be described. FIG. 23 is a sequence diagram showing a method for manufacturing the semiconductor device 30 according to an embodiment of the present invention. FIG. 24 to FIG. 26 are schematic cross-sectional views showing a method for manufacturing the semiconductor device 30 according to an embodiment of the present invention.

The method for manufacturing the semiconductor device 30 of the present embodiment is the same as the manufacturing method described in the second embodiment from the processes of step S1001 to step S1009 shown in FIG. 16 of the second embodiment. The manufacturing method of the present embodiment differs from the manufacturing method of the second embodiment in that step S1201 to step S1203 shown in FIG. 23 are added between step S1009 and step S1110 shown in FIG. 16.

First, as in the second embodiment, the conductive portion 132 is formed by adding impurities to the oxide semiconductor layer 130 by step S1001 to step S1009 in FIG. 16. Next, as shown in FIG. 23 and FIG. 24, a resist mask 220 is again formed on the patterned layer 161 made of an insulator. In this case, as shown in FIG. 24, in the first direction, a width of the resist mask 220 is narrower than the width of the patterned layer 161. Thereafter, the patterned layer 161 is etched using the resist mask 220 as a mask (step S1201 in FIG. 23).

In step S1201, the patterned layer 161 exposed from the resist mask 220 is removed. In the present embodiment, a silicon oxynitride layer is used as the patterned layer 161, and a silicon oxide layer is used as the insulating layer 140. Therefore, since a selective ratio to etching between the patterned layer 161 and the insulating layer 140 is small, the insulating layer 140 exposed from the patterned layer 151 made of a metal oxide is also removed while the patterned layer 161 is being etched.

The etching process of the patterned layer 161 is stopped when a part of the upper surface of the patterned layer 151 located below is exposed. In the present embodiment, since the thickness of the patterned layer 161 is larger than the thickness of the insulating layer 140, the insulating layer 140 directly above the conductive portion 132 is removed, and the conductive portion 132 is exposed.

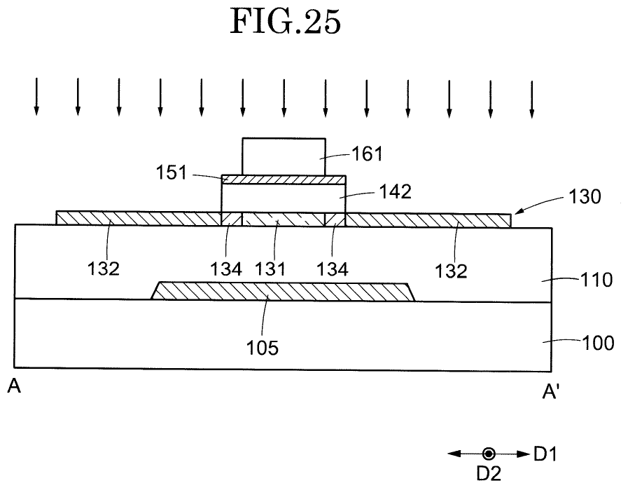

Next, as shown in FIG. 23 and FIG. 25, the resist mask is removed (step S1202 in FIG. 23). Thereafter, the patterned layer 161 is ion-implanted from above, and the oxide semiconductor layer 130 is doped a second time (step S1203 in FIG. 23). As the impurity to be added, the same impurity (phosphorus, boron, argon, or the like) as the impurity addition in step S1009 of FIG. 23 may be used.

The condition of the ion-implantation may be the same as or different from step S1009 of FIG. 23. In the present embodiment, the acceleration is 30 keV and the dose is 1×10¹³/cm². As shown in FIG. 25, in the present embodiment, the LDD portion 134 is formed at an end portion (a portion not overlapping the patterned layer 161) of the channel portion 131 in the first direction by a second doping. In this case, since the impurity is added to the LDD portion 134 via the patterned layer 151 and the insulating layer 140, the quantity of the impurity to be added is smaller than that of the conductive portion 132 even if the impurity is added under the same conditions as in step S1009. That is, a resistance value of the LDD portion 134 is higher than a resistance value of the conductive portion 132.

After the LDD portion 134 is formed through the processes described above, the semiconductor device 30 shown in FIG. 22 is completed through step S1110 to step S1112 shown in FIG. 23. Step S1110 to step S1112 are as described in the second embodiment.

### Modification 1 of Third Embodiment

In the semiconductor device 30 described above, since the patterned layer 151 made of a metal oxide is formed on the insulating layer 140, it has been described that the insulating layer 140 located directly above the conductive portion 132 is removed when step S1201 (etching process of the side portion of the patterned layer 161) of FIG. 23 is performed. However, as described in Modifications 1 and 2 of the second embodiment, in the case where the metal oxide layer 150 is left or completely removed, the final device structure is different.

For example, in Modification 1 of the second embodiment, the metal oxide layer 150 remains on the insulating layer 140 without being etched. In this case, the metallic oxide layer 150 functions as an etching stopper even if step S1201 of FIG. 23 is performed, and thus the insulating layer 140 can be prevented from being etched. In this case, in the device structure of FIG. 22, the insulating layer 140 is arranged in place of the patterned layer 142, and the metal oxide layer 150 is arranged in place of the patterned layer 151.

In addition, in Modification 2 of the second embodiment, the metal oxide layer 150 and the patterned layer 151 do not exist on the insulating layer 140. In the case where step S1201 of FIG. 23 is performed, a portion of the insulating layer 140 that does not overlap the resist mask 220 (that is, a portion that does not overlap the patterned layer 161) is completely removed. Therefore, when the etching process is completed, an end portion of the channel portion 131 (a portion not overlapping the resist mask 220) is exposed. In the process of adding an impurity to the oxide semiconductor layer 130 shown in S1203 of FIG. 23, the dose of the impurity to be added to the LDD portion 134 can be sufficiently increased even if the acceleration voltage is set to be low.

### Modification 2 of Third Embodiment

In the structure shown in FIG. 22, although an example in which the terminal electrode 191 and the conductive portion 132 are electrically connected via the contact hole 181 arranged in the insulating layer 180 is shown, the present invention is not limited to this example. For example, the terminal electrode 191 and the conductive portion 132 can be directly connected to each other without providing the insulating layer 180. After doping the oxide semiconductor layer 130 in the process of S1203 of FIG. 23, a conductive layer covering the oxide semiconductor layer 130 and the patterned layer 161 is formed. Thereafter, the conductive layer may be patterned to form the terminal electrode 191 in contact with the conductive portion 132.

### Fourth Embodiment

In the first embodiment, although an example in which the oxide semiconductor layer 130 is arranged so as to be in contact with the gate insulating layer 110 is shown, a metal oxide layer may be arranged between the gate insulating layer 110 and the oxide semiconductor layer 130. In the description of the present embodiment, the same reference signs are used to denote the same elements as those of the first embodiment, and the description thereof may be omitted.

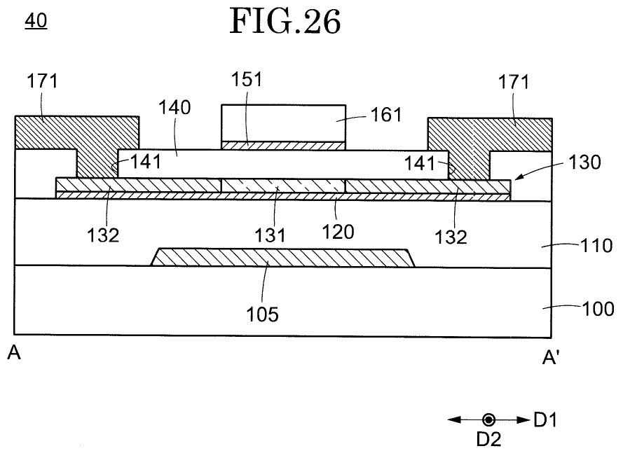

FIG. 26 is a schematic cross-sectional view showing a configuration of a semiconductor device 40 according to an embodiment of the present invention. Although the basic structure is the same as that of the semiconductor device 10 shown in FIG. 1, in the semiconductor device 40 of the present embodiment, the metal oxide layer 120 is arranged between the gate insulating layer 110 and the oxide semiconductor layer 130. In the present embodiment, the metal oxide layer 120 is made of a metal oxide containing aluminum as a main component (specifically, an aluminum oxide (AlOx) layer). The metal oxide layer 120 can be formed by, for example, the sputtering method.

As shown in FIG. 26, in the present embodiment, the metal oxide layer 120 has the same pattern shape as that of the oxide semiconductor layer 130. In the present embodiment, after step S1001 of FIG. 3 is performed, the metal oxide layer 120 and the oxide semiconductor layer 130 are continuously formed. Then, step S1002 and step S1003 of FIG. 3 are processed to obtain the oxide semiconductor layer 130. Further, by etching the oxide semiconductor layer 130 and the metal oxide layer 120, the metal oxide layer 120 having the same pattern shape as that of the oxide semiconductor layer 130 can be formed.

A thickness of the metal oxide layer 120 is, for example, 1 nm or more and 10 nm or less, 1 nm or more and 4 nm or less, or 1 nm or more and 3 nm or less. In the present embodiment, the thickness of the metal oxide layer 120 is defined as 3 nm. In the present embodiment, the aluminum oxide layer used as the metal oxide layer 120 has a high-barrier property against gases even if the thickness is 1 nm or more and 10 nm or less. Therefore, the metal oxide layer 120 of the present embodiment blocks hydrogen and oxygen released from the gate insulating layer 110, and suppresses the hydrogen and oxygen released from below from reaching the oxide semiconductor layer 130.

Blocking the hydrogen released from the gate insulating layer 110 by the metal oxide layer 120 is preferable in order to suppress the reduction reaction of the oxide semiconductor layer 130.

In addition, after the oxide semiconductor layer 130 is formed, more oxygen vacancies are formed on the upper layer side of the oxide semiconductor layer 130 than on the lower layer side in various manufacturing processes (such as a patterning process). That is, the oxygen vacancies in the oxide semiconductor layer 130 exist in a non-uniform distribution in the thickness direction. In this case, if a sufficient amount of oxygen is supplied to repair the oxygen vacancy formed on the upper layer side of the oxide semiconductor layer 130, excessive oxygen is supplied to the lower layer side of the oxide semiconductor layer 130. As a result, a defect level different from the oxygen vacancy may be formed by the excessively supplied oxygen, which may lead to a phenomenon such as a characteristic variation in a reliability test or a decrease in the field-effect mobility. Therefore, blocking the oxygen emitted from the gate insulating layer 110 by the metal oxide layer 120 is also preferable for suppressing excessive oxygen supply to the lower layer side of the oxide semiconductor layer 130.

As described above, in the present embodiment, when the oxidation annealing process shown in step S1005 of FIG. 3 is performed, it is possible to supply oxygen to the upper surface and the side surface of the oxide semiconductor layer 130 having a relatively large amount of oxygen vacancies while suppressing the supply of oxygen to the lower surface of the oxide semiconductor layer 130 having a small amount of oxygen vacancies. Therefore, oxygen can be efficiently supplied to the oxide semiconductor layer 130 during the oxidation annealing process, and reliability of the semiconductor device 40 can be improved.

In addition, in the present embodiment, although an example applied to the semiconductor device 10 shown in FIG. 1 of the first embodiment has been described, it is also applicable to other semiconductor devices shown in the second embodiment or the third embodiment.

### Fifth Embodiment

In the present embodiment, a display device 500 using the semiconductor device 10 according to an embodiment of the present invention will be described. In the embodiments described below, a case where the semiconductor device 10 described in the first embodiment is used as an element constituting a circuit of a liquid crystal display device will be described. However, the present invention is not limited to this example, and the semiconductor devices described in the second to fourth embodiments may be used as the elements constituting the circuit of the liquid crystal display device. Instead of the elements constituting the circuit of the liquid crystal display device, the liquid crystal display device may be used as the elements constituting the circuit of another display device such as an organic EL display device.

### Overview of Display Device

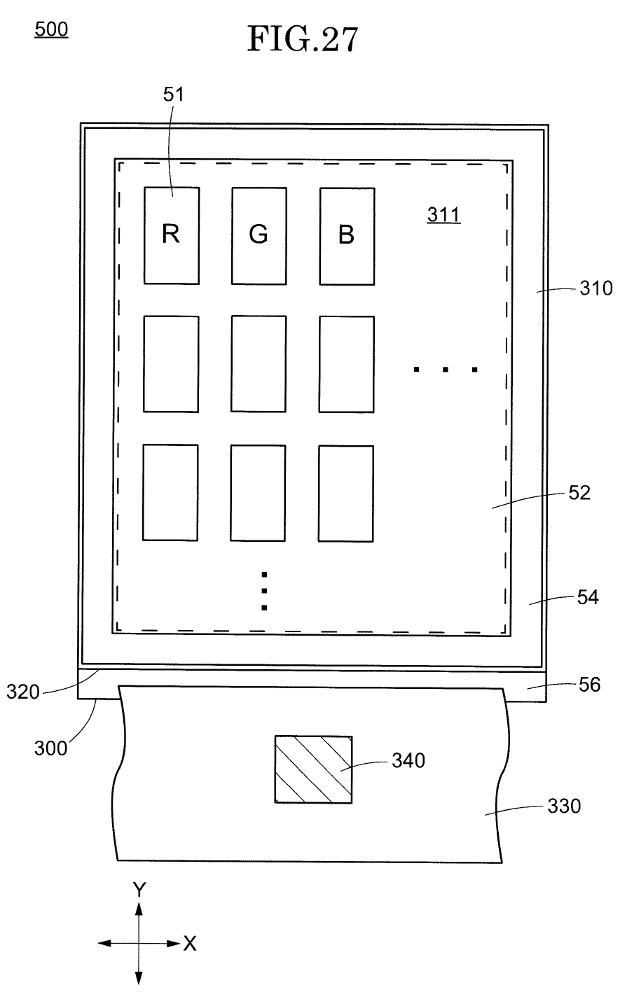

FIG. 27 is a schematic planer view showing the entire configuration of the display device 500 according to an embodiment of the present invention. As shown in FIG. 27, the display device 500 includes an array substrate 300, a seal portion 310, a counter substrate 320, a flexible printed circuit (FPC) board 330, and an IC chip 340. The array substrate 300 and the counter substrate 320 are bonded to each other by the seal portion 310. In a liquid crystal region 52 surrounded by the seal portion 310, a plurality of pixels 51 are arranged in a matrix. That is, a display region is formed by the plurality of pixels 51 arranged side by side in an X direction and a Y direction, respectively. The liquid crystal region 52 is a region overlapping the liquid crystal element 311 described later in planer view. In addition, with respect to the pixel 51, the letters “R”, “G”, and “B” indicate that the letters correspond to the red display pixel, the green display pixel, and the blue display pixel, respectively.

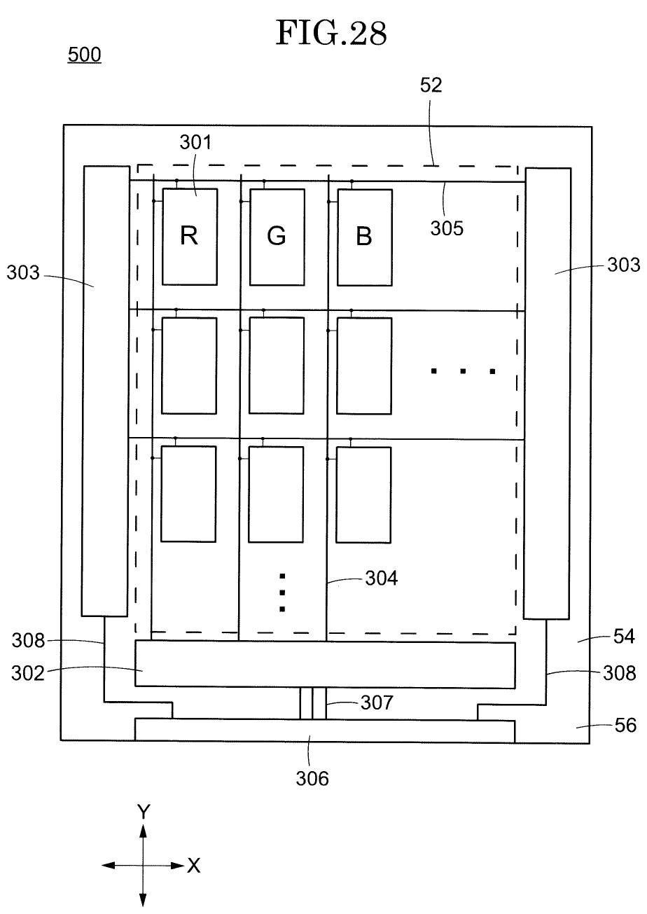

A seal region 54 in which the seal portion 310 is arranged is a region around the liquid crystal region 52. The flexible printed circuit board 330 is arranged in a terminal region 56. The terminal region 56 is a region of the array substrate 300 exposed from the counter substrate 320, and is arranged outside the seal region 54. The outside of the seal region 54 means the outside of the region where the seal portion 310 is arranged and the region surrounded by the seal portion 310. The IC chip 340 is arranged on the flexible printed circuit board 330. The IC chip 340 supplies a signal for driving each pixel circuit 301 (see FIG. 28) arranged in each pixel 51.

### Circuit Configuration of Display Device

FIG. 28 is a block diagram showing a circuit configuration of a display device 500 according to an embodiment of the present invention. As shown in FIG. 28, a plurality of pixel circuits 301 is arranged in a matrix corresponding to the pixels 51 shown in FIG. 27. A source driver circuit 302 is arranged at a position adjacent to the liquid crystal region 52 in which the pixel circuit 301 is arranged in the Y direction (column direction). Further, a gate driver circuit 303 is arranged at a position adjacent to the liquid crystal region 52 in the X direction (row direction). The source driver circuit 302 and the gate driver circuit 303 are arranged in the seal region 54. However, the region in which the source driver circuit 302 and the gate driver circuit 303 are arranged is not limited to the seal region 54, and may be outside the region in which the pixel circuit 301 is arranged.

A data signal line 304 extends from the source driver circuit 302 in the Y direction and is connected to the plurality of pixel circuits 301 arranged in the Y direction. A scanning signal line 305 extends from the gate driver circuit 303 in the X direction, and is connected to the plurality of pixel circuits 301 arranged in the X direction.

A terminal portion 306 is arranged in the terminal region 56. The terminal portion 306 and the source driver circuit 302 are connected by a connection wiring 307. Similarly, the terminal portion 306 and the gate driver circuit 303 are connected by a connection wiring 308. When the flexible printed circuit board 330 is connected to the terminal portion 306, an external device and the display device 500 are connected via the flexible printed circuit board 330. Each pixel circuit 301 arranged in the display device 500 is driven by a signal from an external device input via the flexible printed circuit board 330.

The semiconductor device 10 shown in the first embodiment is used as a switching element or a current control element included in the pixel circuit 301, the source driver circuit 302, and the gate driver circuit 303.

### Pixel Circuit of Display Device

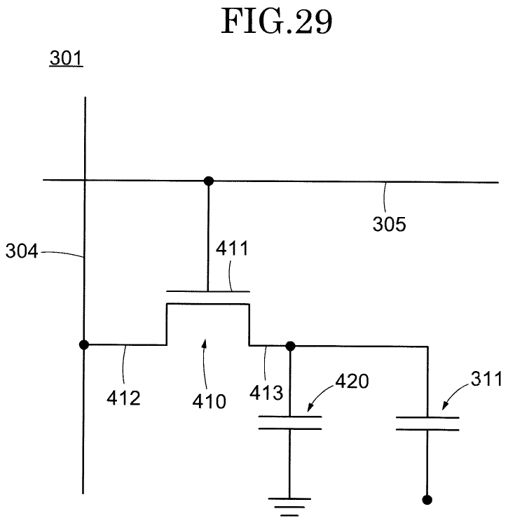

FIG. 29 is a circuit diagram showing a configuration of the pixel circuit 301 of the display device 500 according to the embodiment of the present invention. As shown in FIG. 29, the pixel circuit 301 includes elements such as a switching element 410, a storage capacitor 420, and a liquid crystal element 311.

The switching element 410 is constituted by the semiconductor device 10 of the first embodiment. The switching element 410 includes a gate electrode 411, a source electrode 412, and a drain electrode 413. The gate electrode 411 is connected to the scanning signal line 305. However, the gate electrode 411 and the scanning signal line 305 may be formed of an integral conductive layer. The source electrode 412 is connected to the data signal line 304. However, the source electrode 412 and the data signal line 304 may be formed of an integral conductive layer.

The drain electrode 413 is connected to the storage capacitor 420 and the liquid crystal element 311. In addition, the roles of the source electrode 412 and the drain electrode 413 may be changed depending on the relationship between a voltage supplied to the data signal line 304 and a voltage stored in the storage capacitor 420. That is, the source electrode 412 may function as a drain electrode, and the drain electrode 413 may function as a source electrode.

### Pixel Structure of Display Device

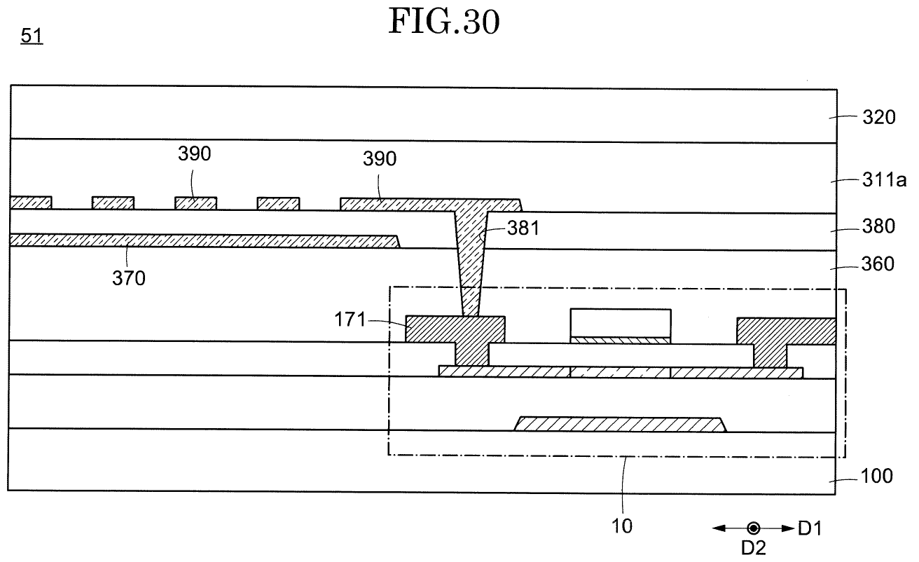

FIG. 30 is a cross-sectional view showing a pixel structure of the display device 500 according to an embodiment of the present invention. In the display device 500, the semiconductor device 10 described in the first embodiment is used as the switching element 410 included in the pixel circuit 301. In the following description, the configuration of the semiconductor device 10 is the same as that of the semiconductor device 10 shown in FIG. 1, and thus a detailed description thereof will be omitted.

An insulating layer 360 is arranged on the terminal electrode 171 of the semiconductor device 10. As the insulating layer 360, for example, an acrylic resin can be used. On the insulating layer 360, a common electrode 370 arranged in common to a plurality of pixels is provided. An insulating layer 380 is arranged on the common electrode 370. As the insulating layer 380, for example, a silicon nitride layer can be used. Contact holes 381 are arranged in the insulating layers 360 and 380. A pixel electrode 390 connected to the terminal electrode 171 via the contact hole 381 is arranged on the insulating layer 380.

As the common electrode 370 and the pixel electrode 390, a transparent conductive layer is used. In the present embodiment, although ITO (Indium Tin Oxide) is used as the transparent conductive layer constituting the common electrode 370 and the pixel electrode 390, another metal oxide layer may be used. The common electrode 370 is formed of a flat transparent conductive layer. Although not shown in FIG. 30, the pixel electrode 390 is formed of a comb-shaped transparent conductive layer in which a portion extending in the first direction and a portion extending in the second direction are combined. The portion extending in the second direction is composed of a plurality of linear electrodes, and is connected to an electrode corresponding to a trunk extending in the first direction.

A liquid crystal layer 311a is sealed between an active matrix substrate formed on the substrate 100 up to the pixel electrodes 390 and the counter substrate 320. The liquid crystal layer 311a is arranged across the plurality of pixels 51. The region in which the liquid crystal layer 311a is arranged corresponds to the liquid crystal region 52 shown in FIG. 27.

As shown in FIG. 30, the common electrode 370 has an overlapping region overlapping the pixel electrode 390 in a planer view and a non-overlapping region not overlapping the pixel electrode 390. When a voltage is supplied between the pixel electrode 390 and the common electrode 370, a lateral electric field is formed from the pixel electrode 390 in the overlapping region toward the common electrode 370 in the non-overlapping region. By operating the liquid crystal molecules contained in the liquid crystal layer 311a by the lateral electric field, gradation of the light passing through the pixel 51 is determined.

Each of the embodiments described above (including the modification examples of each embodiment) as the embodiment of the present invention can be appropriately combined as long as they do not conflict with each other. In addition, any addition, deletion, or changes in conditions of the constituent elements, or addition, omission, or changes in conditions of the steps by a person skilled in the art based on the respective embodiments is also included in the scope of the present invention as long as the present invention is provided.

It is to be understood that the present invention provides other operational effects that are different from the operational effects provided by the aspects of the embodiments described above, and those that are obvious from the description of the present specification or those that can be easily predicted by a person skilled in the art.

What is claimed is:

1. A semiconductor device comprising:
a gate electrode on an insulating surface;
a gate insulating layer on the gate electrode;
an oxide semiconductor layer on the gate insulating layer;
a first insulating layer on the oxide semiconductor layer; and
a first patterned layer composed of an insulating material on the first insulating layer, wherein
the oxide semiconductor layer has a channel portion and a conductive portion, and
the first patterned layer overlaps the channel portion in a planar view.

2. The semiconductor device according to claim 1 wherein
an outer edge of a portion of the first patterned layer overlapping the oxide semiconductor layer coincides with an outer edge of the channel portion in a planar view.

3. The semiconductor device according to claim 1 wherein
the channel portion and the conductive portion are arranged continuously in a first direction, and
the first patterned layer intersects the oxide semiconductor layer in a second direction intersecting the first direction in a planar view.

4. The semiconductor device according to claim 1 wherein
the first patterned layer is composed of an insulating material containing silicon.

5. The semiconductor device according to claim 1 wherein
a thickness of the first insulating layer is 200 nm or less.

6. The semiconductor device according to claim 1 wherein
the first insulating layer is in contact with the oxide semiconductor layer.

7. The semiconductor device according to claim 6 wherein
the first insulating layer includes one selected from an oxide silicon layer, a nitride oxide silicon layer, or an oxide nitride silicon layer.

8. The semiconductor device according to claim 1 further comprising
a terminal electrode arranged on the first insulating layer and electrically connected to the conductive portion.

9. The semiconductor device according to claim 1 further comprising
a metal oxide layer containing aluminum between the first insulating layer and the first patterned layer.

10. The semiconductor device according to claim 1 further comprising
a second patterned layer composed of a metal oxide between the first insulating layer and the first patterned layer.

11. The semiconductor device according to claim 10 wherein
the second patterned layer has the same pattern shape as the first patterned layer.

12. The semiconductor device according to claim 1 further comprising
a second insulating layer on the first patterned layer, and
a terminal electrode arranged on the second insulating layer and electrically connected to the conductive portion.

13. The semiconductor device according to claim 12 wherein
the second insulating layer includes a silicon nitride layer.

14. The semiconductor device according to claim 1 wherein
the oxide semiconductor layer has an LDD portion between the channel portion and the conductive portion.

15. The semiconductor device according to claim 14 wherein
the LDD portion has a lower resistance value than the channel portion and a higher resistance value than the conductive portion.

16. The semiconductor device according to claim 14 wherein
a position of an edge of the first patterned layer and a position of an edge of the LDD portion on the channel portion side are aligned in a vertical direction.

17. The semiconductor device according to claim 1 further comprising
a metal oxide layer containing aluminum between the gate insulating layer and the oxide semiconductor layer, the metal oxide layer being in contact with the oxide semiconductor layer.

18. The semiconductor device according to claim 17 wherein
the metal oxide layer has the same pattern shape as the oxide semiconductor layer.
